(19) United States
(12) Patent Application Publication
(10) Pub. No.: US 2009/0065040 A1
(43) Pub. Date: Mar. 12, 2009

(54) Electrical energy generating device

(76) Inventor: Nikolai Tatarinov, Zelenogorsk City (RU)

Correspondence Address: LAW OFFICE OF DALE B. HALLING, LLC, 655 SOUTHPOINTE CT, SUITE 100, COLORADO SPRINGS, CO, 80906, US

(21) Appl. No.: 12/070,658

(22) Filed: Feb. 20, 2008

(30) Foreign Application Priority Data
Sep. 9, 2007 (RU) 2007135317(038615

(51) Int. Cl. H01L 35/00

(52) U.S. Cl. 136/205

(57) ABSTRACT

The invention results in an increased efficiency factor at electric energy generation. To achieve the mentioned technical result an electric energy generating device has a heat energy source, means for bringing heat energy from the source to an energy converter, heat-to-electric energy converter, and means of supplying the obtained electric energy to the mains. The heat-to-electric energy converter has at least, one converging module, including an irradiator with thermal luminescent coating, IR photo-cell, and concentrator that faces the irradiator with thermal luminescent coating and concentrates IR radiation directly onto the IR photo-cell, which is connected with the means for supplying the obtained electric energy to the mains. The device also differs in that each converting module is covered with heat insulation material from the outside, and also in that the means for supplying the obtained electric energy to the mains is made as an inverter.

### BACKGROUND OF THE INVENTION

The invention relates to the sphere of power engineering and can be used for electric energy generation.

Known is a method of electric energy generation based on converting energy obtained through combustible materials burning into mechanical and then into electric energy [I. P. Kopylov, Electrical Machines. M: Energoatmizdat, 1986, p. 348-349]. A plant, operating to this method, includes, as a rule, a heat energy source that actuates a turbine that, in its turn, actuates an electric generator, generating electric current.

Known are energy generating devices based on converting energy obtained, for instance, through combustible materials burning, into electric energy with the aid of thermopiles (See SU 435430 F 02 N 17/02, 1974).

The drawback to this method and device is an extremely low efficiency factor, resulting from energy losses occurring in the process of converting heat energy into electric one.

### BRIEF SUMMARY OF INVENTION

The claimed inventions' technical result is an increased efficiency factor at electric energy generation.

To achieve the mentioned technical result, an electric energy generating device, includes a heat energy source, means for bringing heat energy from the source to an energy converter, heat-to-electric energy converter, and means of supplying the obtained electric energy to the mains, at this, the heat-to-electric energy converter includes at least, one converging module, including an irradiator with thermal luminescent coating, IR photo-cell, and concentrator that faces the irradiator with thermal luminescent coating and concentrates IR radiation directly onto the IR photo-cell, which is connected with the means, supplying the obtained electric energy to the mains. The device also differs in that each converting module is covered with heat insulation material from the outside, and also in that the means of supplying the obtained electric energy to the mains is made as an inverter, converting direct current into alternating current of standard voltage.

### BRIEF DESCRIPTION OF THE SEVERAL VIEWS OF THE DRAWINGS

FIG. 1. is a functional electric diagram of the device in accordance with one embodiment of the invention; and

FIG. 2. is a block diagram of a converting module in accordance with one embodiment of the invention.

### DETAILED DESCRIPTION OF THE INVENTION

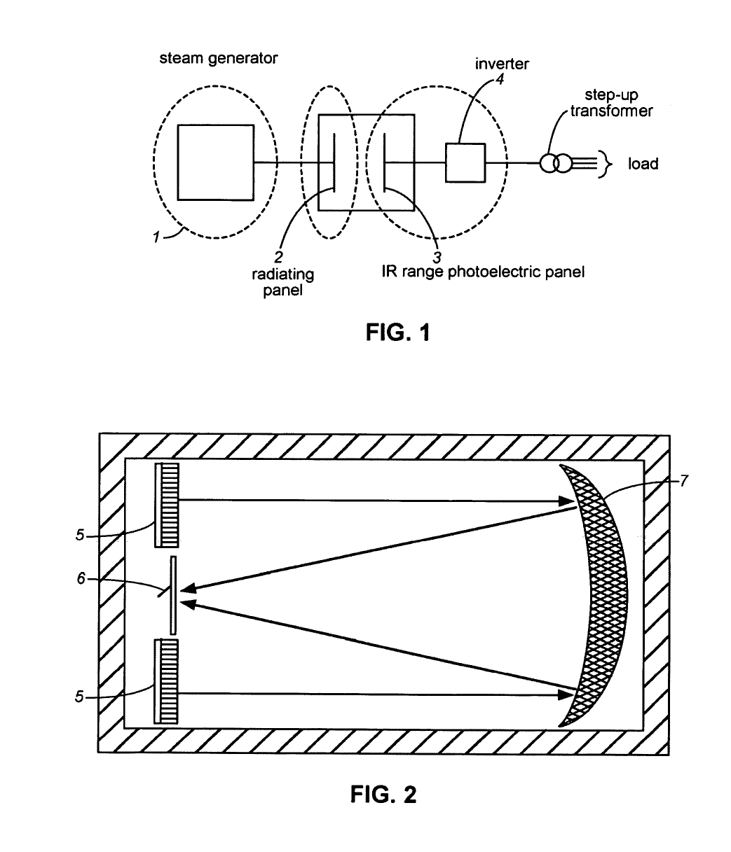

An electric energy generating device has a heat energy source 1 (see FIG. 1), multitude of converting modules 3, connected with heat energy source 1 through means for bringing heat energy 2. Each of converting modules 2, 3 is electrically connected with means of supplying the obtained electric energy to the mains 4. Means of supplying the obtained electric energy to the mains 4, may consist of an inverter that, in its turn, is electrically connected with a step-up transformer. Each of converting modules 2, 3 has heated irradiator with thermal luminescent coating 5 (See FIG. 2), IR photo-cell 6, and concentrator 7. Each irradiator with thermal luminescent coating 5 is opposed by concentrator 7 that concentrates IR radiation directly onto IR photo-cell 6, known, for instance, from the description to RF patent No 2222846 (H01L31/04, published on 27 Jan. 2004). Converting module 3 is heat insulated to prevent heat losses. Heat obtained from heat energy source 1, is directed through means of bringing heat energy 2, to converting modules 3, that can be installed in endless multitude depending on how much electric energy is required. Heated irradiators with thermal luminescent coating 5, in their turn, irradiate heat energy in IR range to concentrator 7 made as a parabolic or differently shaped reflecting mirror, in which focus IR photo-cell 6 is located that converts this IR radiation into electric energy. With the aid of inverters (any of the known suitable inverters can be used) direct current obtained from IR photo-cell 6, is converted into alternating current of standard voltage (380V, 6 kW etc.) and through step-up transformers is directed to the mains for further consumer supply. The irradiator's special thermal luminescent coating is meant for obtaining IR radiation of a shorter band than is obtained with a standard black coating at the same temperature. Ideal (when heated to 150-350° C.) is a transfer to a visible radiation range.

At this, heat losses of the electric energy plant as a whole make about 15%: with outgoing gases of the steam generator and through the heat insulation of steam lines and converting modules-12%, in inverters and transformers about 3%. When the known “steam generator-steam turbine-electric generator-transformer” arrangement is used, heat losses make about 60% at this some losses occur in the turbine condenser (about 5%).

While the invention has been described in conjunction with specific embodiments thereof, it is evident that many alterations, modifications, and variations will be apparent to those skilled in the art in light of the foregoing description. Accordingly, it is intended to embrace all such alterations, modifications, and variations in the appended claims.

What is claimed is:

1. An electric energy generating device, comprising:
a heat energy source,
means for bringing heat energy from the source to an energy converter,
heat-to-electric energy converter, and
means for supplying the obtained electric energy to the mains, wherein the heat-to-electric energy converter comprises, at least, one converting module, including, at least, one irradiator with thermal luminescent coating, IR photo-cell, and concentrator that faces the irradiator with thermal luminescent coating and concentrates IR radiation directly onto the IR photo-cell, which is connected with the means, supplying the obtained electric energy to the mains.

2. The device of claim 1, wherein each converting module is covered with heat insulation material from the outside.

3. The device of claim 1, wherein the means for supplying the obtained electric energy to the mains, is made as an inverter, converting direct current into alternating current of standard voltage.
